(19) United States
(12) Patent Application Publication
(10) Pub. No.: US 2006/0054907 A1
(43) Pub. Date: Mar. 16, 2006

(54) Light-emitting device of gallium nitride-based III-V group compound semiconductor

(76) Inventor: Mu-Jen Lai, Chungli City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/982,795

(22) Filed: Nov. 8, 2004

(30) Foreign Application Priority Data
Sep. 16, 2004 (TW) 093214832

(51) Int. Cl. H01L 29/221

(52) U.S. Cl. 257/96

(57) ABSTRACT

A light-emitting device of gallium nitride-based III-V group compound semiconductor includes a substrate, a texturing surface area arranged over the substrate; a n-type gallium nitride-based III-V group compound semiconductor layer having an ohmic contact area with texturing surface disposed over the substrate; a light-emitting layer arranged over the n-type gallium nitride-based III-V group compound semiconductor layer; a p-type gallium nitride-based III-V group compound semiconductor layer disposed over the light-emitting layer; a texturing surface layer covered over the p-type gallium nitride-based III-V group compound semiconductor layer; a transparent conductive oxide layer arranged over the texturing surface layer and establishing an ohmic contact with the texturing surface layer; a first electrode electrically coupling with the ohmic contact area with texturing surface of the n-type gallium nitride-based III-V group compound semiconductor layer; a second electrode electrically coupling with the transparent conductive oxide layer.

### BACKGROUND OF THE INVENTION

The present invention relates to a light-emitting device of gallium nitride-based III-V group compound semiconductor, especially to a light-emitting device with higher light extraction efficiency.

Refer to FIG. 1, the conventional epitaxy structure of gallium nitride-based III-V group compound semiconductor light-emitting device 1′ is disclosed. The prior invention includes a sapphire substrate 10′, a gallium nitride buffer layer 15′, a n-type gallium nitride contact layer 20′, an indium gallium nitride (InGaN) emitting layer 30′, a p-type gallium nitride layer 40′, a p-type gallium nitride contact layer 42′. Then remove part of the a n-type gallium nitride contact layer 20′, an indium gallium nitride (InGaN) emitting layer 30′, a p-type gallium nitride layer 40′, a p-type gallium nitride contact layer 42′ so as to make part of the surface of the n-type gallium nitride contact layer 20′ expose. This step of manufacturing process is called mesa etching. Then a transparent conductive layer 50′ made of Ni/Au is formed over the p-type gallium nitride contact layer 42′ while a p-type metal electrode 70′ is over the transparent conductive layer 50′. And a n-type metal electrode 60′ is over the n-type gallium nitride contact layer 20′ to form a lateral electrode.

Moreover, refer to FIG. 2, using a device with the length and width of 350 μm×350 μm as an example, the p-type metal electrode 70′ and the n-type metal electrode 60′ represent about 20% of the total area of the device while the exposed surface of the n-type gallium nitride contact layer 20′ accounts for 35% of the total area of the device. When turn-on current is applied to the p-type metal electrode 70′ and the n-type metal electrode 60′ so as to make the indium gallium nitride emitting layer 30′ emit light. The path of the emitted light is shown in FIG. 3. Part of the light is radiated directly as path A and part of the light is radiated after several times of reflection, as path B. Part of the light emitted forward is not only shielded by the p-type metal electrode 70′ and the n-type metal electrode 60′, but also is absorbed by the transparent conductive layer 50′.

Furthermore, the refractive index of the epitaxial structure formed of gallium nitride is about 2.4, the refractive index of the sapphire substrate is about 1.77, and the refractive index of the packaging resin is about 1.5. Due to the waveguide effect, part of the light emitting from the light-emitting layer is reflected by the sapphire substrate and the packaging resin and then is re-absorbed by the multi-layer epitaxyial structure of gallium nitride. Thus the light extraction efficiency is decreased.

In addition, in order to increase the light extraction efficiency of the device, the optical transparency of the transparent conductive layer is increased or a Distributed Bragg Reflector (DBR) layer is added under the light emitting layer. However, both methods can only increase the light extraction efficiency of the emitting light along vertical direction, not break the waveguide effect. For breaking the waveguide effect, a texturing surface or a rough surface is provided on the surface of the light-emitting device compound semiconductor so as to reduce reflection of light through various interfaces with different refractive indices. During the growth of the epitaxy, the texturing or rough surface are formed artificially, please refer to Taiwanese patent application No. 092132987, the process has been described therein. In order to increase the light extraction efficiency and reduce the operating voltage, a structure is disclosed in Taiwanese patent application No. 93105169 whose applicant is the same with the present invention. A conventional transparent conductive layer made of Ni/Au is replaced by a transparent conductive oxide layer whose optical transmittance is better than Ni/Au and has good ohmic contact with the texturing surface ohmic contact layer so as to reduce the operating voltage.

Furthermore, the refractive index of the exposed surface of the n-type gallium nitride contact layer is about 2.4 and the refractive index of the packaging resin is about 1.5 so that the critical angle of the device is 38 degrees. Only the light entered at an angle smaller than the critical angle, it is transmitted and leaves the device. The light at an angle greater than the critical angle is totally reflected back into the deice Therefore, the light extraction efficiency is limited. The structure with exposed sapphire substrate has the same problem. However, once the surface of the n-type gallium nitride contact layer or the sapphire substrate is modified into a texturing or rough surface, the total internal reflection is reduced. Thus the light extraction efficiency is improved.

### SUMMARY OF THE INVENTION

Therefore, it is a primary object of the present invention to provide a light-emitting device of gallium nitride-based III-V group compound semiconductor that reduces the total internal reflection produced by the critical angle by a texturing surface area over the substrate so as to improve the light extraction efficiency.

It is a further object of the present invention to provide a light-emitting device of gallium nitride-based III-V group compound semiconductor that reduces the total internal reflection produced by the critical angle by a texturing surface over the ohmic contact area of the n-type gallium nitride-based III-V group compound semiconductor layer so as to improve the light extraction efficiency.

In order to achieve the objects mentioned above, the present invention includes a substrate with a texturing surface area arranged thereover; a n-type gallium nitride-based III-V group compound semiconductor layer having an ohmic contact area with texturing surface disposed over the substrate; a light-emitting layer arranged over the n-type gallium nitride-based III-V group compound semiconductor layer; a p-type gallium nitride-based III-V group compound semiconductor layer disposed over the light-emitting layer; a texturing surface layer covered over the p-type gallium nitride-based III-V group compound semiconductor layer; a transparent conductive oxide layer arranged over the texturing surface layer and establishing an ohmic contact with the texturing surface layer; a first electrode electrically coupling with the ohmic contact area with texturing surface of the n-type gallium nitride-based III-V group compound semiconductor layer; a second electrode electrically coupling with the transparent conductive oxide layer.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein FIG. 1 is a schematic diagram of a prior art of a light-emitting gallium nitride-based III-V group compound semiconductor device.

FIG. 2 is a top view of a prior art of a light-emitting gallium nitride-based III-V group compound semiconductor device;

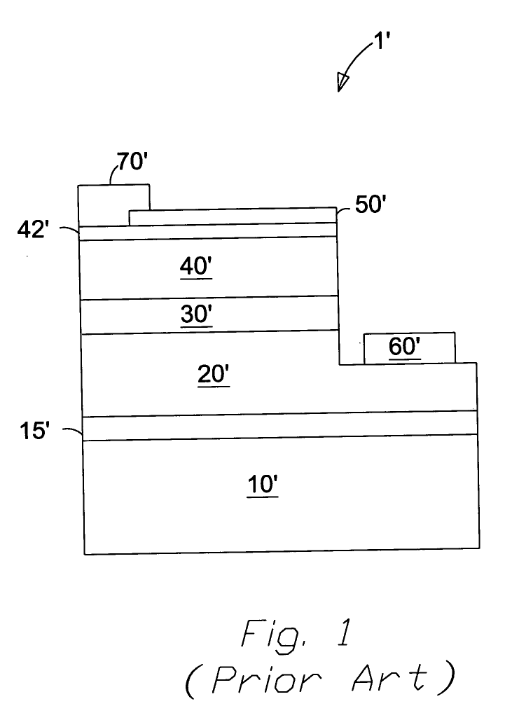

FIG. 3 is a diagram showing the light path emitted from a light-emitting layer of a prior art;

FIG. 4 is a schematic diagram of a better embodiment of a light-emitting gallium nitride-based III-V group compound semiconductor device in accordance with the present invention;

FIG. 5 is a flow chart of texturing surface on a light-emitting gallium nitride-based III-V group compound semiconductor device in accordance with the present invention;

FIG. 6 is a schematic diagram of a further better embodiment of a light-emitting gallium nitride-based III-V group compound semiconductor device in accordance with the present invention.

### DETAILED DESCRIPTION OF THE PREFFERED EMBODIMENT

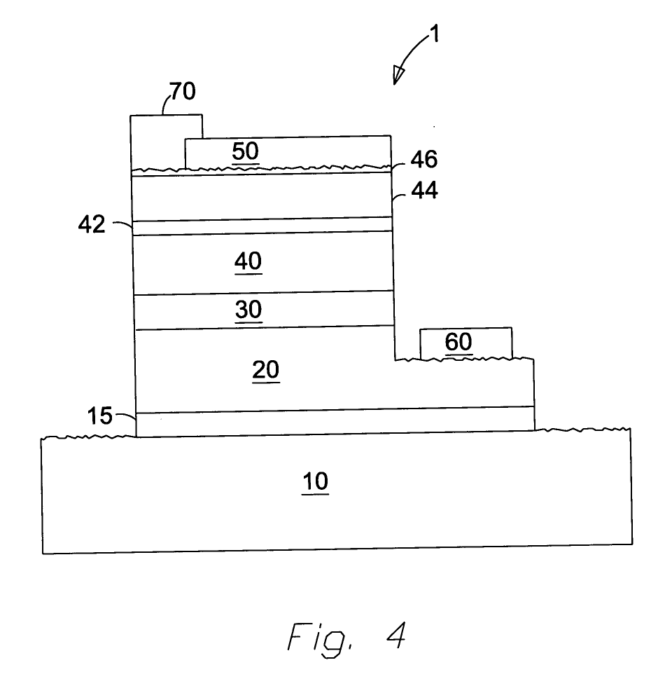

Refer to FIG. 4, a better embodiment of the present invention is disclosed. A light-emitting device 1 of gallium nitride-based III-V group compound semiconductor includes a substrate layer 10, a first-type gallium nitride-based III-V group compound semiconductor ohmic contact layer 20, a light-emitting layer (active layer) 30, a second-type gallium nitride-based III-V group compound semiconductor (cladding) layer 40, second-type gallium nitride-based III-V group compound semiconductor contact layer 42, a second ohmic contact layer 44, a window layer 50, a first electrode 60 and a second electrode 70, wherein over the substrate 10 further having a buffer layer 15.

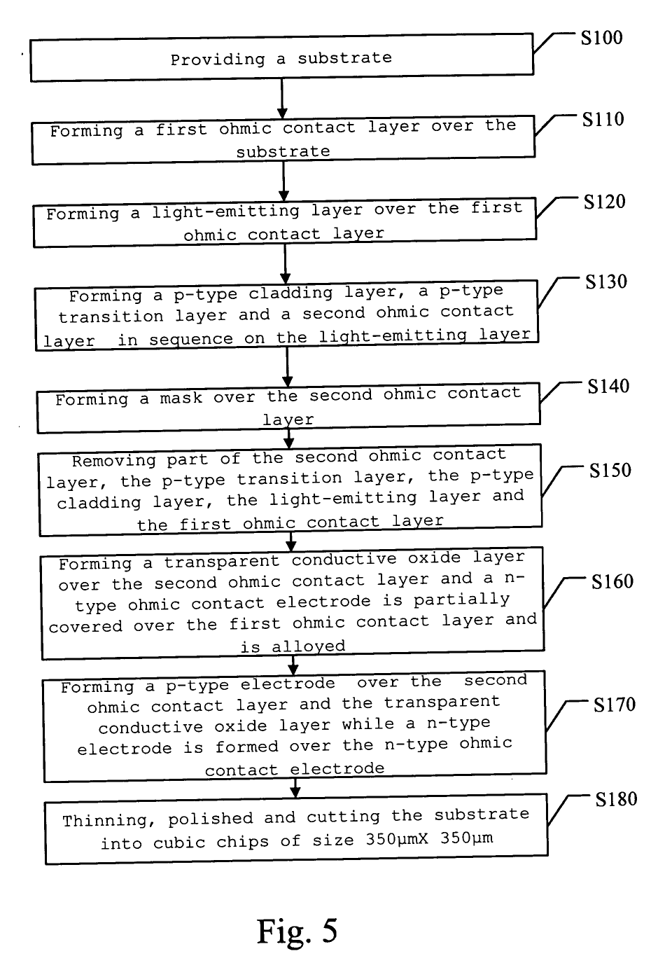

The substrate 10 is made of sapphire, zinc oxide (ZnO), or silicon carbide. The first-type ohmic contact layer 20 is an n-doped gallium nitride (GaN), aluminum indium gallium nitride (AlInGaN), or indium gallium nitride (InGaN) layer. The second-type gallium nitride-based III-V group compound semiconductor layer 40 is a p-doped gallium nitride (GaN), aluminum indium gallium nitride (AlInGaN), or indium gallium nitride (InGaN) layer. The light-emitting layer (active layer) 30 is formed of a nitride compound semiconductors having indium. The window layer 50 is a transparent conductive oxide layer made of an indium oxide, tin oxide, indium molybdenum oxide, indium cerium oxide, zinc oxide, indium zinc oxide (IZO), magnesium zinc oxide, tin cadmium oxide, or indium tin oxide (ITO).The surface of both the first-type ohmic contact layer 20 and the a second layer of ohmic contact layer 44 is a texturing surface or a rough surface. As to the formation of the texturing surface or the rough surface, please refer to FIG. 5. This is a flow chart of manufacturing process of the epitaxy and chips. The steps of the present invention include:
Step S100, a substrate is provided;
Step S110, a first ohmic contact layer is formed over the substrate;
Step S120, a light-emitting layer is formed over the first ohmic contact layer;
Step S130, a p-type cladding layer, a p-type transition layer and a second ohmic contact layer are formed in sequence on the light-emitting layer, wherein the second ohmic contact layer having a texturing surface or a rough surface;
Step S140, a mask is formed over the second ohmic contact layer;
Step S150, part of the second ohmic contact layer, the p-type transition layer, the p-type cladding layer, the light-emitting layer and the first ohmic contact layer are removed by dry etch techniques such as reactive ion etching (RIE) or inductively coupled plasma etching (ICP); during the process, the etch-rate is controlled so as to make the etch-rate in vertical direction larger than the etch-rate in horizontal direction; thus the texturing or rough surface on the second ohmic contact layer is replicated on the surface of the first ohmic contact layer;
Step S160, a transparent conductive oxide layer is formed over the second ohmic contact layer and a n-type ohmic contact electrode is partially covered over the first ohmic contact layer and is alloyed;
Step S170, a p-type electrode is formed over the second ohmic contact layer and the transparent conductive oxide layer while a n-type electrode is formed over the n-type ohmic contact electrode;
Step S180, the substrate is thinning, polished and cut into cubic chips of size 350 μm×350 μm.

In accordance with the embodiment mentioned above, the texturing or rough surface is replicated on the sapphire substrate. After taking the step S130, use a first mask to remove part of the second ohmic contact layer, the p-type transition layer, the p-type cladding layer, the light-emitting layer, the first ohmic contact layer and the sapphire substrate by the same method mentioned in the step S150. Thus the texturing or rough surface is replicated on the surface of the sapphire substrate. Then a second mark is used for processing from the step S140 to the step S180.

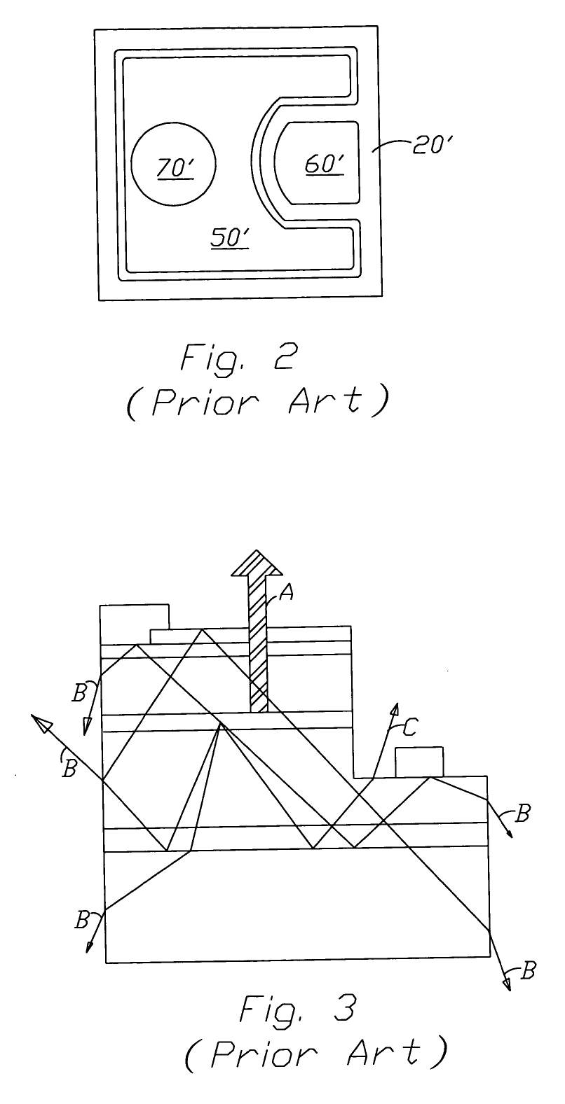

The texturing surface layer 46 on the surface of the second ohmic contact layer 44 is artificially controlled during the growth of epitaxy. Please refer to Taiwanese patent application No. 092132987, the process has been described therein. When a p-type cladding layer and a p-type transition layer are formed, the strain of the tension and compression is controlled. Then a p-type ohmic contact layer is formed over the p-type transition layer. By this way, a texturing structure formed on the surface of the p-type semiconductor. Therefore, the resistance between the window layer 50 and the p-type gallium nitride-based III-V group compound semiconductor is reduced and is turned into an excellent ohmic contact layer. The operating voltage of the LED is also reduced. Moreover, the texturing surface layer 46 can be p-doped, n-doped, or co-doped gallium nitride-based III-V group compound semiconductor layer. Refer to FIG. 3 again, when the first-type ohmic contact layer 20 having a texturing or rough surface structure, the light extraction efficiency is improved due to the increase of light path C that is caused by reduction of the total internal reflection.

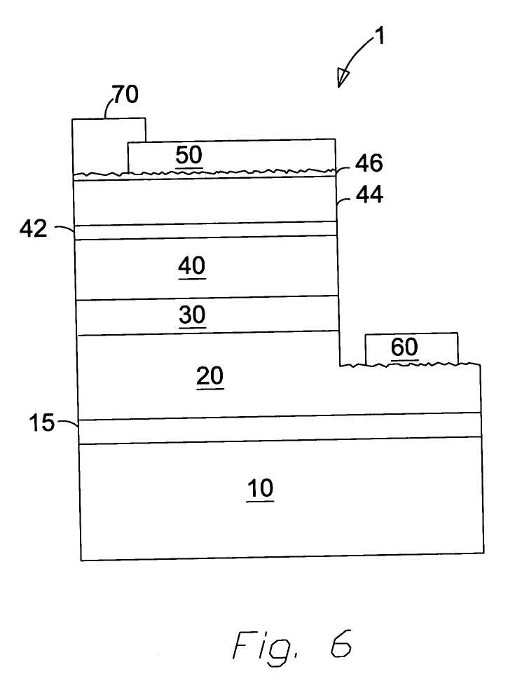

Refer to FIG. 6, a further embodiment of the present invention is disclosed. The invention 1 includes a substrate 10, a first-type ohmic contact layer 20, a light-emitting layer (active layer) 30, a second-type gallium nitride-based III-V group compound semiconductor cladding layer 40, second-type gallium nitride-based III-V group compound semiconductor contact layer 42, a second ohmic contact layer 44, a window layer 50, a first electrode 60 and a second electrode 70, wherein over the substrate 10 further having a buffer layer 15. The surface of both the first-type ohmic contact layer 20 and the second ohmic contact layer 44 is texturing or rough surface and is formed by the same method mentioned in FIG. 5.

Additional advantages and modifications will readily occur to those skilled in the art. Therefore, the invention in its broader aspects is not limited to the specific details, and representative devices shown and described herein. Accordingly, various modifications may be made without departing from the spirit or scope of the general inventive concept as defined by the appended claims and their equivalents.

What is claimed is:

1. A light-emitting device of gallium nitride-based III-V group compound semiconductor comprising:
a substrate;
a n-type gallium nitride-based III-V group compound semiconductor layer having an ohmic contact area with texturing surface, arranged over said substrate;
a light-emitting layer disposed over said n-type gallium nitride-based III-V group compound semiconductor layer;
a p-type gallium nitride-based III-V group compound semiconductor layer arranged over said light-emitting layer;
a texturing surface layer covered over said p-type gallium nitride-based III-V group compound semiconductor layer; a transparent conductive oxide layer arranged over said texturing surface layer and establishing an ohmic contact with said texturing surface layer;
a first electrode electrically coupling with said ohmic contact area with texturing surface of said n-type gallium nitride-based III-V group compound semiconductor layer;
a second electrode electrically coupling with said transparent conductive oxide layer.

2. The device according to claim 1, wherein said texturing surface layer is formed during the growth of epitaxy.

3. The device according to claim 1, wherein said ohmic contact area with texturing surface of said n-type gallium nitride-based III-V group compound semiconductor layer is formed by etching part of said texturing surface layer, said p-type gallium nitride-based III-V group compound semiconductor layer, said light-emitting layer and said n-type gallium nitride-based III-V group compound semiconductor layer during a manufacturing process of chips.

4. The device according to claim 1, wherein said substrate further having a texturing surface area arranged thereover.

5. The device according to claim 4, wherein said texturing surface area of said substrate is formed by etching part of said texturing surface layer, said p-type gallium nitride-based III-V group compound semiconductor layer, said light-emitting layer and said n-type gallium nitride-based III-V group compound semiconductor layer during a manufacturing process of chips.

6. The device according to claim 1, wherein said transparent conductive oxide layer is made of an indium oxide, tin oxide, indium molybdenum oxide, indium cerium oxide, zinc oxide, indium zinc oxide, magnesium zinc oxide, tin cadmium oxide, or indium tin oxide.

7. A light-emitting device of gallium nitride-based III-V group compound semiconductor comprising:
a substrate;
a n-type gallium nitride-based III-V group compound semiconductor layer having an ohmic contact area with texturing surface, arranged over said substrate;
a light-emitting layer disposed over said n-type gallium nitride-based III-V group compound semiconductor layer;
a p-type gallium nitride-based III-V group compound semiconductor layer arranged over said light-emitting layer.

8. The device according to claim 7, wherein a texturing surface layer is arranged over said p-type gallium nitride-based III-V group compound semiconductor layer.

9. The device according to claim 8, wherein a transparent conductive oxide layer is arranged over said texturing surface layer.

10. The device according to claim 7, wherein a first electrode is electrically coupling with said ohmic contact area with texturing surface of said n-type gallium nitride-based III-V group compound semiconductor layer.

11. The device according to claim 7, wherein a second electrode is electrically coupling with said transparent conductive oxide layer.

12. The device according to claim 7, wherein said texturing surface layer is formed during the growth of epitaxy.

13. The device according to claim 7, wherein said ohmic contact area with texturing surface of said n-type gallium nitride-based III-V group compound semiconductor layer is formed by etching part of said texturing surface layer, said p-type gallium nitride-based III-V group compound semiconductor layer, said light-emitting layer and said n-type gallium nitride-based III-V group compound semiconductor layer during a manufacturing process of chips.

14. The device according to claim 7, wherein said transparent conductive oxide layer is made of an indium oxide, tin oxide, indium molybdenum oxide, indium cerium oxide, zinc oxide, indium zinc oxide, magnesium zinc oxide, tin cadmium oxide, or indium tin oxide.

15. A light-emitting device of gallium nitride-based III-V group compound semiconductor comprising:
a substrate with a texturing surface area thereover;
a n-type gallium nitride-based III-V group compound semiconductor layer arranged over said substrate;
a light-emitting layer disposed over said n-type gallium nitride-based III-V group compound semiconductor layer;
a p-type gallium nitride-based III-V group compound semiconductor layer arranged over said light-emitting layer.

16. The device according to claim 15, wherein said a texturing surface layer is arranged over said p-type gallium nitride-based III-V group compound semiconductor layer.

17. The device according to claim 16, wherein a transparent conductive oxide layer is arranged over said texturing surface layer.

18. The device according to claim 15, wherein said n-type gallium nitride-based III-V group compound semiconductor layer further having an ohmic contact area with texturing surface and is electrically coupling with said ohmic contact area with texturing surface.

19. The device according to claim 18, wherein a first electrode is electrically coupling with said ohmic contact area with texturing surface of said n-type gallium nitride-based III-V group compound semiconductor layer.

20. The device according to claim 17, wherein a second electrode is electrically coupling with said transparent conductive oxide layer.

21. The device according to claim 15, wherein said texturing surface layer is formed during the growth of epitaxy.

22. The device according to claim 18, wherein said said ohmic contact area with texturing surface of said n-type gallium nitride-based III-V group compound semiconductor layer is formed by etching part of said texturing surface layer, said p-type gallium nitride-based III-V group compound semiconductor layer, said light-emitting layer and said n-type gallium nitride-based III-V group compound semiconductor layer during a manufacturing process of chips.

23. The device according to claim 15, wherein said transparent conductive oxide layer is made of an indium oxide, tin oxide, indium molybdenum oxide, indium cerium oxide, zinc oxide, indium zinc oxide, magnesium zinc oxide, tin cadmium oxide, or indium tin oxide.
